(19) United States
(12) Patent Application Publication
(10) Pub. No.: US 2026/0305244 A1
(43) Pub. Date: Oct. 1, 2026

(54) LOAD PORT, ABNORMAL STATE DETERMINATION METHOD, AND STORAGE MEDIUM

(71) Applicant: Hirata Corporation, Kumamoto-shi (JP)

(72) Inventor: Takumi Hirano, Kumamoto-shi (JP)

(21) Appl. No.: 19/576,179

(22) Filed: Mar. 24, 2026

(30) Foreign Application Priority Data
Mar. 26, 2025 (JP) 2025-052695

(51) Int. Cl. H10P 72/30; H10P 72/00; H10P 72/50

(52) U.S. Cl. CPC H10P 72/3411; H10P 72/0608; H10P 72/3408; H10P 72/53

(57) ABSTRACT

According to present disclosure, there is provided a load port including: a placement portion at which is placed a container accommodating a substrate; a plate that has an opening portion through which the substrate is inserted and removed; a port door that opens and closes the opening portion and includes an engaging portion configured to engage with an engagement portion of a lid of the container; a drive mechanism that moves the port door; a detection unit; and a control unit that controls an operation of each unit. The control unit moves the port door from an attachment position in a vicinity of the plate to a detection position between the attachment position and a retracted position separated from the plate, detects whether or not the port door holds the lid by the detection unit in a state in which the port door is stopped at the detection position, and determines whether or not there is an abnormal state related to an attachment state of the lid based on a detection result of the detection unit.

### CROSS-REFERENCE TO RELATED APPLICATIONS

This application claims priority under 35 U.S.C. § 119 from Japanese Patent Application No. 2025-052695, filed on Mar. 26, 2025. The entire disclosure of Japanese Patent Application No. 2025-052695 is hereby incorporated herein by reference.

### BACKGROUND OF THE INVENTION

### Field of the Invention

The present disclosure relates to a load port, an abnormal state determination method, and a storage medium.

### Description of the Related Art

In a semiconductor manufacturing apparatus, plural substrates such as semiconductor wafers to be processed are accommodated in a container called a front opening unified pod (FOUP) and are transferred between semiconductor manufacturing apparatuses. The substrate is accommodated in the FOUP by being placed on a slot of the FOUP, and is inserted and removed via an opening portion provided in the FOUP by a transfer arm in the semiconductor manufacturing apparatus. The FOUP is mounted on a mounting table of a load port of the semiconductor manufacturing apparatus, and the opening portion is opened and closed by attaching and detaching a lid of the FOUP by an opening/closing mechanism provided in the load port. After the opening portion of the FOUP is closed, the lid is locked by a latch mechanism.

In a case in which the lid is not appropriately attached or is not locked, when the FOUP is transferred between the semiconductor manufacturing apparatuses, the lid may fall off from the FOUP, and the substrate may protrude from the FOUP.

For example, Japanese Patent No. 6816249 discloses a technique of providing, in order to confirm whether or not a lid is appropriately attached to the FOUP, a lid holding sensor unit including a closure sensor that detects the presence or absence of a lid attachment/detachment mechanism at an attachment position and an abnormal state detection sensor that detects the presence or absence of an object; moving the lid attachment/detachment mechanism between an attachment position at which the lid attachment/detachment mechanism contacts the lid disposed at the position of the opening portion and a retracted position at which the lid attachment/detachment mechanism does not contact the lid disposed at the position of the opening portion; and determining the presence or absence of an abnormal state related to attachment/detachment of the lid by using the lid holding sensor unit.

### SUMMARY OF THE INVENTION

The technique disclosed in Japanese Patent No. 6816249 determines the presence or absence of an abnormal state related to attachment and detachment of the lid based on a time difference between a timing at which the closure sensor stops to detect the lid attachment/detachment mechanism when the lid attachment/detachment mechanism moves from the attachment position to the retracted position and a timing at which the abnormal state detection sensor stops detecting an object when the lid attachment/detachment mechanism moves from the attachment position to the retracted position.

In the technique disclosed in Japanese Patent No. 6816249, it is difficult to determine that a state in which the lid is not properly locked and the lid attachment/detachment mechanism holds the lid in a separated state is abnormal. The reason for this is that, in a case in which the lid attachment/detachment mechanism holds the lid in a separated state, the timing at which the abnormal state detection sensor stops detecting an object is the same as the timing in a case in which the holding state of the lid is normal, and as a result, there is a risk that the state will be determined as normal.

Therefore, an object of the present disclosure is to provide a load port and an abnormal state determination method capable of more accurately determining an attachment abnormal state of the lid with a simple configuration.

In order to solve the above problem, according to a first aspect of the present invention, there is provided a load port including: a placement portion at which is placed a container accommodating a substrate; a plate that has an opening portion through which the substrate is inserted and removed, in a state in which the opening portion is adjacent to the container; a port door that opens and closes the opening portion, that includes an engaging portion configured to engage with an engagement portion of a lid of the container, and that holds the lid; a drive mechanism that moves the port door to an attachment position in a vicinity of the plate, a retracted position separated from the plate, and a detection position between the attachment position and the retracted position; a detection unit that detects at least the lid; and a control unit that controls an operation of each unit, in which the engaging portion protrudes from a holding surface of the port door, a protrusion amount of the engaging portion being smaller than a thickness direction dimension of the lid that is held, the lid has a second surface at an opposite side from a first surface, the first surface facing the port door, the control unit moves the port door from the attachment position to the detection position, and determines a normal state or an abnormal state related to an attachment state of the lid based on a detection result of the detection unit in a state in which the port door is stopped at the detection position, and the detection position is a position at which a detection region of the detection unit overlaps with a region between a tip portion of the engaging portion and the second surface of the lid in a case in which the first surface of the lid is contacting the holding surface of the port door.

According to a second aspect of the present invention, in the load port according to the first aspect, the detection unit is provided in the plate, and the control unit sets, as the detection position, a position of the port door when the region overlaps with the detection region, moves the port door, and determines an attachment state of the lid attached to the container.

According to a third aspect of the present invention, in the load port according to the first aspect, the control unit moves the port door from the attachment position to the detection position based on a command value input to an input unit, and stops the port door when the port door reaches the detection position, and the command value is one or any combination of a movement distance or a movement time from the attachment position to the detection position.

According to a fourth aspect of the present invention, in the load port according to the first aspect, the detection unit includes optical sensors including a light projecting unit and a light receiving unit, and the light projecting unit and the light receiving unit are disposed above and below a center portion of the plate in a horizontal direction with the opening portion interposed therebetween.

According to a fifth aspect of the present invention, in the load port according to the first aspect, in a case in which it is determined that attachment of the lid is normal, the control unit moves the port door that is stopped at the detection position from the detection position to the attachment position, and in a case in which it is determined that attachment of the lid is abnormal, the control unit outputs an alarm in a state in which the port door is stopped at the detection position.

According to a sixth aspect of the present invention, in the load port according to the first aspect, the detection unit further detects the substrate protruding from the container, and the control unit determines a protrusion state of the substrate from the container in a case in which the port door that holds the lid is located at the retracted position.

According to a seventh aspect of the present invention, in the load port according to the first aspect, the normal state is a state in which the detection unit detects that there is no object present in the detection region in a case in which the port door is located at the detection position, and the abnormal state is a state in which the detection unit detects that there is an object present in the detection region in a case in which the port door is located at the detection position.

According to an eighth aspect of the present invention, there is provided an abnormal state determination method performed by a load port, the load port including a placement portion at which is placed a container accommodating a substrate, a plate that has an opening portion through which the substrate is inserted and removed, in a state in which the opening portion is adjacent to the container, a port door that opens and closes the opening portion and that includes an engaging portion configured to engage with an engagement portion of a lid of the container, a drive mechanism that moves the port door to an attachment position in a vicinity of the plate, a retracted position separated from the plate, and a detection position between the attachment position and the retracted position, a detection unit that detects at least the lid, and a control unit that controls an operation of each unit, the engaging portion protruding from a holding surface of the port door, a protrusion amount of the engaging portion being smaller than a thickness direction dimension of the lid that is held, and the lid having a second surface at an opposite side from a first surface, the first surface facing the port door, the method including: detecting, by the detection unit, a state of the lid attached to the container in a state in which the port door is moved from the attachment position to the detection position and the port door is stopped at the detection position; and determining a normal state or an abnormal state related to an attachment state of the lid based on a detection result of the detection unit, in which the detecting includes a movement step of moving the drive mechanism to a position at which a detection region of the detection unit overlaps with a region between a tip portion of the engaging portion and the second surface of the lid in a case in which the first surface of the lid is contacting the holding surface of the port door.

According to a ninth aspect of the present invention, in the abnormal state determination method according to the eighth aspect, in a case in which it is determined that an attachment state of the lid is normal, the port door that is stopped at the detection position is moved from the detection position to the attachment position.

According to a tenth aspect of the present invention, there is provided a storage medium, storing a program causing the control unit to execute the abnormal state determination method according to the eighth aspect or the ninth aspect.

### Advantageous Effects of Invention

According to the present disclosure, it is possible to provide a load port and an abnormal state determination method capable of more accurately determining an attachment abnormal state of the lid with a simple configuration.

### BRIEF DESCRIPTION OF THE DRAWINGS

FIG. 1 is a schematic side sectional view of a load port according to an embodiment of the present invention;

FIG. 2 is an enlarged schematic view of a plate portion of the load port of FIG. 1;

FIG. 3 is an explanatory diagram of a port door that holds a lid of a container in the load port of FIG. 1 and is disposed at a detection position;

FIG. 4A to FIG. 4C are diagrams illustrating movement of the port door according to an embodiment of the present invention, FIG. 4A is an explanatory diagram illustrating a state where the port door is disposed at an attachment position, FIG. 4B is an explanatory diagram illustrating a state where the port door is disposed at a detection position, and FIG. 4C is an explanatory diagram illustrating a state where the port door is disposed at a retracted position;

FIG. 5A and FIG. 5B are diagrams illustrating a range of the port door in a case where the lid of the container is in close contact with the port door in the embodiment of the present invention, FIG. 5A illustrates a state where the port door is located at a detection position at which a detection region of a detection unit is closest to a tip portion of the engaging portion, and FIG. 5B illustrates a state where the port door is located at a detection position at which a detection region of a detection unit is closest to a second surface of the lid;

FIG. 6A and FIG. 6B are diagrams illustrating the port door in a case where the lid of the container is separated from the port door in the embodiment of the present invention, FIG. 6A illustrates a state where the port door is located at a detection position at which a detection region of a detection unit is closest to a tip portion of an engaging portion, and FIG. 6B illustrates a state where the port door is located at a detection position at which a detection region of a detection unit is closest to a second surface of the lid;

FIG. 7 is a block diagram of a control unit of the load port according to the embodiment of the present invention;

FIG. 8 is a flowchart illustrating an abnormal state determination method of the load port according to the embodiment of the present invention;

FIG. 9A and FIG. 9B are schematic diagrams illustrating patterns of abnormalities, FIG. 9A illustrates a case where the lid is held in a state of being in contact with a holding surface of the port door, and FIG. 9B illustrates a case where the lid is held in a state of being separated from the port door;

FIG. 10 is a timing chart of an abnormal state determination method of the load port according to the embodiment of the present invention, A illustrates a normal case, B illustrates a case where the port door holds the lid in a state of being in contact with the lid, and C illustrates a case where the port door holds the lid in a separated state; and

FIG. 11 is a schematic diagram of a drive unit of the load port according to the embodiment of the present invention.

### DETAILED DESCRIPTION OF THE INVENTION

Hereinafter, an embodiment of the present invention (hereinafter, simply referred to as “present embodiment”) will be described in detail. The following embodiment is an example for explaining the present invention, and is not intended to limit the present invention to the following content. The present invention can be appropriately modified and implemented within the scope of the gist thereof. In the drawings, the same components are denoted by the same reference numerals, and redundant description will be omitted. In addition, unless otherwise specified, a positional relationship such as up, down, left, and right is based on the positional relationship illustrated in the drawings. Further, dimensional ratios in the drawings are not limited to the illustrated ratios.

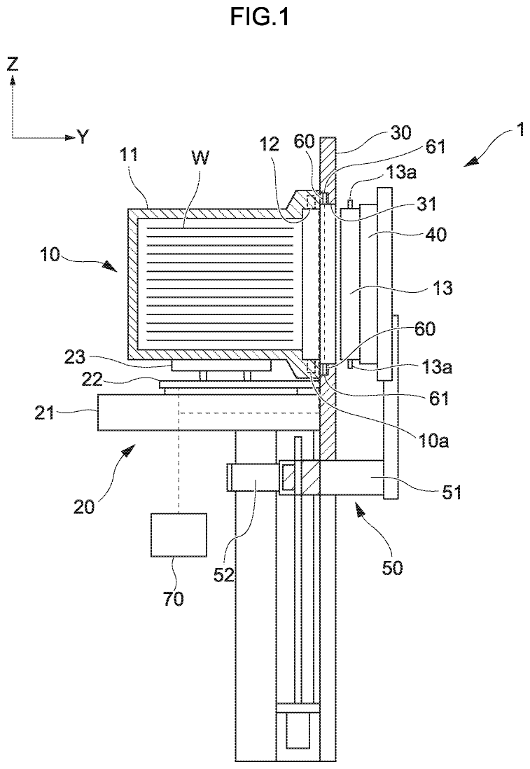

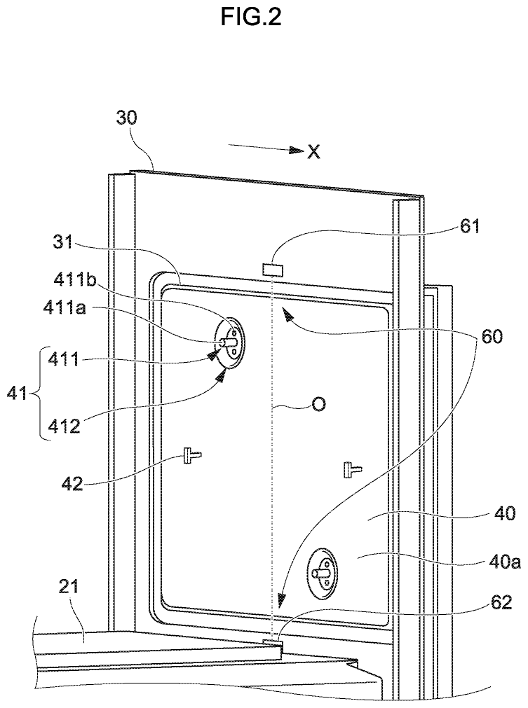

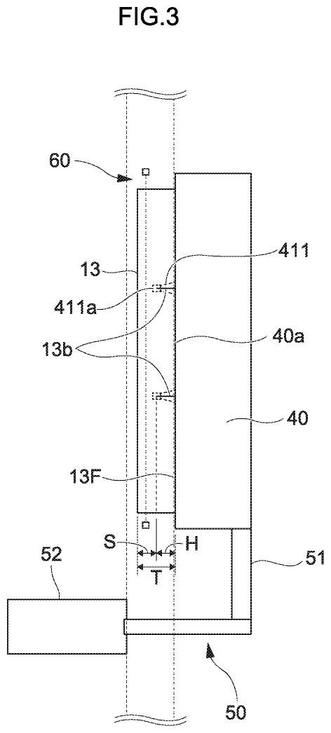

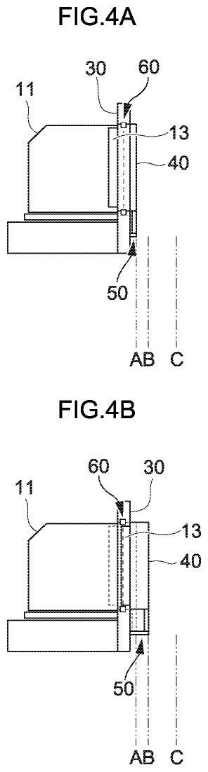

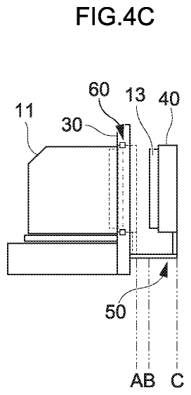

FIG. 1 is a schematic side sectional view of a load port according to an embodiment of the present invention. FIG. 2 is an enlarged schematic view of a plate portion of the load port of FIG. 1. FIG. 3 is an explanatory diagram of a port door that holds a lid of a container in the load port of FIG. 1 and is arranged at a detection position. FIG. 4A to FIG. 4C are diagrams illustrating movement of a port door according to an embodiment of the present invention, FIG. 4A is an explanatory diagram illustrating a state where the port door is disposed at an attachment position, FIG. 4B is an explanatory diagram illustrating a state where the port door is disposed at a detection position, and FIG. 4C is an explanatory diagram illustrating a state where the port door is disposed at a retracted position.

As illustrated in FIG. 1, a load port 1 according to the present embodiment includes a placement portion 20 on which a container 10 is placed, a plate 30, a port door 40, a drive mechanism 50, a detection unit 60, and a control unit 70 that controls an operation of each unit. The control unit 70 determines the presence or absence of an abnormal state related to attachment and detachment of a lid 13 based on a detection result of the detection unit 60. The control unit 70 determines the presence or absence of a substrate W protruding from the container 10 based on the detection result of the detection unit 60.

The container 10 includes a main body portion 11 having an opening portion 12 and a lid 13. The container 10 may be, for example, a FOUP, and can accommodate a plurality of substrates W placed on slots in a state in which surfaces of the substrates W face upward. The container 10 is provided with an opening portion 12, and the opening portion 12 is sealed by the lid 13. The lid 13 is provided with latches 13a and 13a, and the lid 13 is fixed to the main body portion 11 of the container 10 by the latches 13a and 13a. The container 10 is transferred by a transfer device such as an overhead hoist transport (OHT, overhead-traveling automated guided vehicle) in a state of being sealed by the lid 13.

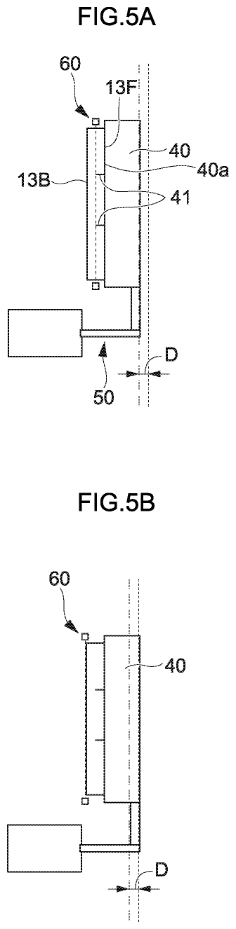

The lid 13 of the container 10 has a second surface (an inner surface) 13B on the opposite side of a first surface (an outer surface) 13F (refer to FIG. 5A). An engagement portion 13b (refer to FIG. 3) that is to be engaged with an engaging portion 411 of the port door 40 to be described later is provided on the first surface 13F. Further, the first surface 13F has a locking hole (not illustrated) that is to be used when the lid 13 is fitted into the FOUP and then is locked by a locking mechanism 42 of the port door 40 to be described later.

The placement portion 20 includes a base 21, a placement table 23 on which the container 10 in which the substrate W is accommodated is placed, and a movement mechanism 22 that is incorporated in the base 21 and moves the placement table 23 in a horizontal direction (a Y-axis direction in FIG. 1). For example, the container 10 transferred by the transfer device such as the OHT is placed on the placement table 23 that is in a standby state in a negative Y-axis direction side, and the placement table 23 is moved to the plate 30 side (a positive Y-axis direction) by the movement mechanism 22 and is attached to the load port 1.

As illustrated in FIG. 1, the plate 30 is provided to extend in a vertical direction at an end portion of the base 21 of the placement portion 20. The plate 30 forms a connection portion between a substrate transfer device (not illustrated) (for example, an equipment front end module (EFEM)) that transfers the substrate W to and from a process device that performs various types of processing on the substrate W and the load port 1, and also serves as a partition wall between a processing region and the outside. The plate 30 has an opening portion 31 in a region extending upward from the base 21, and the substrate W is inserted and removed from the opening portion 31 in a state in which the placement table 23 moves toward the plate 30 side and the container 10 and the plate 30 are in contact with each other.

As illustrated in FIG. 2, the port door 40 is fitted into the opening portion 31 of the plate 30 to close the opening portion 31 in a standby state when the container 10 is not attached. The port door 40 includes a holding portion 41. The holding portion 41 includes an engaging portion 411 and a suction pad 412. The engaging portion 411 engages with the engagement portion 13b of the lid 13 of the container 10. The engaging portion 411 is provided with a suction hole 411b connected to a suction device, and after the engaging portion 411 is engaged with the engagement portion 13b of the lid 13, a vacuum state is formed through the suction hole 411b. Thereby, the inside of the suction pad 412 has a negative pressure, and thus, the lid 13 can be held. In addition, the port door 40 is provided with a locking mechanism 42. By inserting the locking mechanism 42 into a locking hole (not illustrated) of the lid 13 and rotating the locking mechanism 42, the latch 13a of the lid 13 is operated, and thus, unlocking/locking of the lid 13 is performed.

When the container 10 is attached, as illustrated in FIG. 5A, a holding surface 40a of the port door 40 comes into contact with the first surface 13F of the lid 13. At this time, the engagement portion 13b of the lid 13 is engaged with the engaging portion 411 of the port door 40, and the locking hole of the lid 13 is engaged with the locking mechanism 42 of the port door 40. The lid 13 is unlocked by the locking mechanism 42, and the lid 13 is held by the engaging portion 411. Thus, the lid 13 can be removed.

The port door 40 is moved toward the rear side in the horizontal direction (the positive Y-axis direction) by the drive mechanism 50 while holding the lid 13 by the engaging portion 411, and the opening portion 12 of the container 10 and the opening portion 31 of the plate 30 are opened by removing the lid 13. Thereafter, the port door 40 is moved downward in the vertical direction (a negative Z-axis direction) by the drive mechanism 50. At this time, the detection unit 60 may detect protrusion of the substrate W. Then, the container 10 is opened toward the substrate transfer device, and a transfer arm (not illustrated) in the substrate transfer device can access the container 10. The transfer arm holds one or a plurality of substrates W accommodated in the container 10, and transfers the substrates W to a subsequent process device.

The substrate W that has been processed by the process device is transferred to the container 10 by the substrate transfer device. When closing the lid 13 of the container 10 in which the substrate W that has been processed by the process device is accommodated, the port door 40 moves upward in the vertical direction (a positive Z-axis direction) while holding the lid 13. At this time, the detection unit 60 may detect protrusion of the substrate W. Then, the lid 13 is moved to the front side in the horizontal direction (the negative Y-axis direction), and is fitted into the opening portion 12 of the container 10. The locking mechanism 42 is inserted into the locking hole, and the latch 13a of the lid 13 is operated. Thus, the lid 13 is fixed to the container 10. As described above, the port door 40 opens and closes the opening portion 12 of the container 10 and the opening portion 31 of the plate 30.

As illustrated in FIG. 2 and FIG. 3, the engaging portions 411 of the port door 40 protrude at positions shifted to the left side and the right side from the center on the holding surface 40a of the port door 40, and are configured to engage with the engagement portions 13b of the lid 13. The protrusion amount H of the engaging portion 411 is smaller than a thickness direction dimension T of the lid 13 to be held. Note that the engaging portion 411 may be, for example, a registration pin and the protrusion amount H may be approximately 11 mm. Further, the thickness of the lid 13 may be approximately 26 mm.

As illustrated in FIG. 3, the drive mechanism 50 includes an arm portion 51 that is connected to the port door 40, extends downward in the vertical direction, and is bent in the horizontal direction, and a drive portion 52 that is connected to an end portion of the arm portion 51. In the drive mechanism 50, for example, as illustrated in FIG. 1, the drive portion 52 is slidably fitted into a rail that extends in the vertical direction and is disposed in a lower portion of the placement table 23, and moves the port door 40 in the vertical direction along the rail.

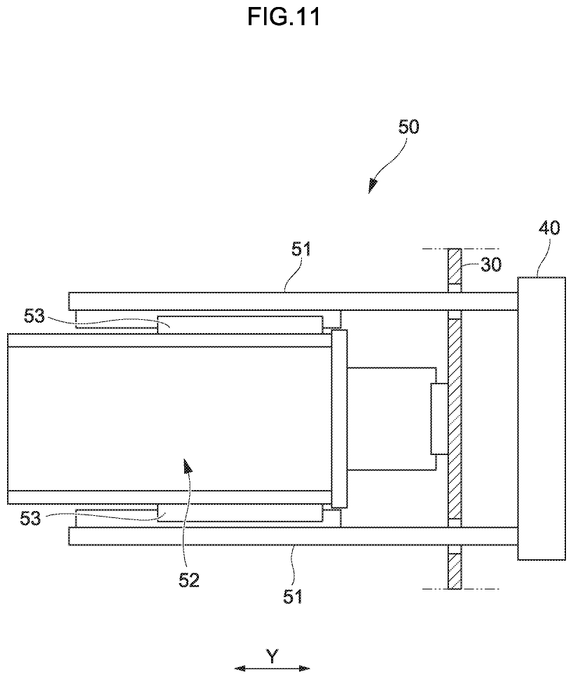

Further, the arm portion 51 is movable in the horizontal direction by the drive portion 52, and thus, the port door 40 can be moved in the horizontal direction. For example, as illustrated in FIG. 11, the arm portion 51 is slidably engaged with a linear guide 53 of the drive portion 52. In this way, the arm portion 51 moves the port door 40 in the horizontal direction along the linear guide 53.

As illustrated in FIG. 4A to FIG. 4C, in the present embodiment, the drive mechanism 50 moves the port door 40 to an attachment position A (FIG. 4A) close to the plate 30, a retracted position C (FIG. 4C) separated from the plate, and a detection position B (FIG. 4B) between the attachment position A and the retracted position C. The attachment position A is a position at which the holding surface 40a of the port door 40 comes into contact with the first surface 13F of the lid 13 in a state in which the container 10 is sealed with the lid 13. The detection position B is a position at which the port door 40 that holds the lid 13 is moved in the horizontal direction from the attachment position A and is disposed, and is a position at which a region S to be described later can be detected by the detection unit 60. The retracted position is a position at which the port door 40 is separated from the plate 30 and can move in the vertical direction.

As illustrated in FIG. 2, the detection unit 60 includes, for example, a pair of optical sensors, and includes a light projecting unit 61 and a light receiving unit 62. In the present embodiment, the light projecting unit 61 and the light receiving unit 62 are disposed above and below the center of the plate 30 with the opening portion 31 interposed therebetween in the horizontal direction (the X-axis direction). When light from the light projecting unit 61 is detected by the light receiving unit 62, it is determined that there is no object in a space of the opening portion 31, and on the other hand, when light from the light projecting unit 61 is not detected by the light receiving unit 62, it is determined that there is an object in a space of the opening portion 31. Examples of the object include the lid 13 and the substrate W. Further, in the present embodiment, the detection unit 60 is provided in the plate 30.

In the present embodiment, when the port door 40 is disposed at the detection position B, movement of the drive mechanism is stopped, and the optical sensors disposed in the opening portion 31 are operated to determine the presence or absence of the lid 13. When the port door 40 is disposed at the detection position B, the presence or absence of the lid 13 is detected by the optical sensors. When the lid 13 is included in a detection region O of the detection unit 60, it is determined that there is an object. The detection region O is an optical axis (indicated by a dotted line in FIG. 2) extending from the light projecting unit 61 toward the light receiving unit 62.

In the present embodiment, the detection unit 60 is configured using the optical sensors, but is not limited thereto. For example, the presence or absence of the lid 13 may be detected based on an image obtained by using an imaging device such as a CCD camera.

In addition, when the port door 40 moves up and down from the retracted position C, the optical sensors disposed in the opening portion 31 are operated to determine whether the substrate W accommodated in the main body portion 11 of the container 10 protrudes from the opening portion 12. When the port door 40 moves up and down from the retracted position, the optical sensors detect whether or not the substrate W protrudes. When the substrate W is included in the detection region O of the detection unit 60, it is determined that the substrate W protrudes.

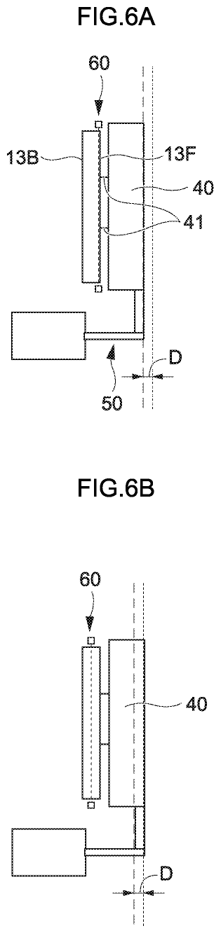

In the present embodiment, the control unit determines a normal state or an abnormal state related to the attachment state of the lid based on the detection result of the detection unit 60. Specifically, after the container 10 is sealed with the lid 13 and the lid 13 is locked by the locking mechanism 42, in a case where the engaging portion 411 of the port door 40 holds the lid 13 in a separated state (refer to FIG. 6A and FIG. 6B), it is also determined that an abnormal state is detected. At this time, when a region S of the lid 13 in a case where the port door 40 holds the lid 13 is included in the detection region O of the detection unit 60 described above, by detecting the presence or absence of the lid 13, an abnormal state is determined. The position of the port door 40 disposed at this time means the detection position in the present embodiment.

Here, as illustrated in FIG. 3, the region S means a region between a tip portion 411a of the engaging portion 411 of the port door 40 and the second surface 13B of the lid 13 in a state in which the first surface 13F of the lid 13 comes into contact with the holding surface 40a of the port door 40.

The region S will be described in more detail with reference to FIG. 5A to FIG. 6B. A broken line indicates a position of the port door in a case where the detection region O of the detection unit 60 is closest to the tip portion 411a of the engaging portion 411, and a dotted line indicates a position of the port door in a case where the detection region O of the detection unit 60 is closest to the second surface 13B of the lid 13. Note that, in any case, the position of the port door 40 corresponds to the detection position.

FIG. 5A and FIG. 5B are diagrams illustrating the port door 40 in a case where the lid 13 of the container 10 is in close contact with the port door 40. FIG. 6A and FIG. 6B are diagrams illustrating the port door 40 in a case where the lid 13 of the container 10 is separated from the port door 40.

FIG. 5A is a diagram illustrating a state where the port door is located at the detection position B at which the detection region O of the detection unit 60 is closest to the tip portion 411a of the engaging portion 411, and FIG. 5B is a diagram illustrating a state where the port door is located at the detection position B at which the detection region O of the detection unit 60 is closest to the second surface 13B of the lid 13.

The drive mechanism 50 operates the port door 40 such that the region S and the detection region O of the detection unit 60 overlap each other, and thus, the port door is located at the detection position B. In other words, the port door 40 is located at the detection position B by the drive mechanism 50. When the port door 40 is located at the detection position B by the drive mechanism 50, the region S overlaps the detection region O of the detection unit 60. That is, the available detection position B of the port door 40 is a range D indicated by an arrow in FIG. 5A and FIG. 5B.

In both FIG. 5A and FIG. 5B, since the lid 13 is included in the detection region O of the detection unit 60, the presence of the lid 13 is detected. As will be described later, when the presence of the lid 13 is detected, it is determined that there is an abnormal state.

Next, a case where the lid 13 of the container 10 is separated from the port door 40 as illustrated in FIG. 6A and FIG. 6B will be described. FIG. 6A is a diagram illustrating a state where the port door is located at the detection position at which the detection region O of the detection unit 60 is closest to the tip portion 411a of the engaging portion 411, and FIG. 6B is a diagram illustrating a state where the port door is located at the detection position at which the detection region O of the detection unit 60 is closest to the second surface 13B of the lid 13.

When the drive mechanism 50 is operated to move the port door 40 to the same position as the position in FIG. 5A, as illustrated in FIG. 6A, the first surface 13F of the lid 13 is located in the detection region O of the detection unit 60. In addition, when the port door 40 is moved to the same position as the position in FIG. 5B, as illustrated in FIG. 6B, the lid 13 is located in the detection region O of the detection unit 60. That is, even in a case where the lid 13 of the container 10 is separated from the port door 40 as illustrated in FIG. 6A and FIG. 6B, the lid 13 is included in the detection region O of the detection unit 60, and thus, the detection unit 60 can detect the presence of the lid 13. Therefore, it is determined that there is an abnormal state due to the presence of the lid 13.

As described above, in the present disclosure, by setting the region S in which a plurality of assumed abnormal states can be detected and setting, as the detection position B, the position of the port door 40 when the detection region O of the detection unit 60 overlaps the region S, it is possible to more accurately determine an abnormal state. That is, according to the present disclosure, even in a mode in which abnormal states are different from each other, it is possible to determine an abnormal state under a common condition.

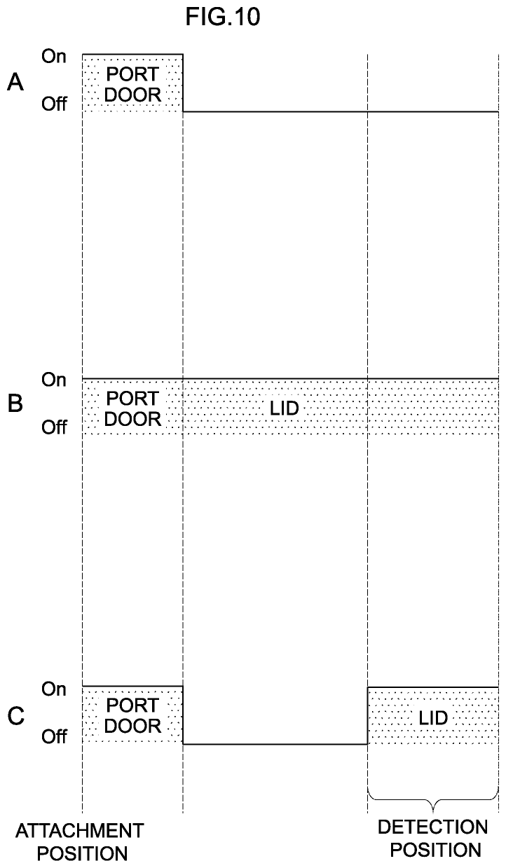

Advantageous effects obtained by setting the detection position as described above will be described with reference to FIG. 10. FIG. 10 illustrates a timing chart of an abnormal state determination step S2 after the container 10 is sealed with the lid 13 and the lid 13 is locked by the locking mechanism 42. A illustrates a normal state, B illustrates a case where the port door 40 is in contact with the lid 13 and holds the lid 13, and C illustrates a case where the port door 40 holds the lid 13 in a separated state. Note that, in FIG. 10, “On” indicates a state where the detection unit 60 detects an object, and “Off” indicates a state where the detection unit 60 does not detect an object.

As illustrated in A of FIG. 10, since the port door 40 is disposed in the detection region O at the attachment position A, a detection result of the detection unit 60 is On. Thereafter, in a normal case, a detection result of the detection unit 60 is Off while the port door 40 moves from the attachment position A to the detection position B, and also maintains Off at the detection position B. In the present embodiment, in a case where the detection result at the detection position B is Off, it is detected that there is no object, and thus, it is determined that there is no abnormal state (normal).

On the other hand, in a case where the port door 40 is in contact with the lid 13 and holds the lid 13, as illustrated in B of FIG. 10, a detection result of the detection unit 60 is not Off while the port door 40 moves from the attachment position A to the detection position B, and maintains On until the port door 40 reaches the detection position B. That is, in such a case, the port door 40 is disposed in the detection region O at the attachment position A, and then the lid 13 is disposed in the detection region O while the port door 40 moves to the detection position B. Therefore, it is detected that an object is present at the detection position B. In the present embodiment, in a case where the detection result at the detection position B is On, it is determined that there is an abnormal state due to the presence of the object.

In the present embodiment, it is also possible to determine an abnormal state even in a case where the port door 40 holds the lid 13 in a separated state. In this case, the lid 13 is in a state of being caught and held by the engaging portion 411, and the position of the engaging portion 411 does not overlap the optical axis (detection region O) of the detection unit 60. Thus, the engaging portion 411 is not detected by the detection unit 60. Therefore, as illustrated in C of FIG. 10, while the port door 40 moves from the attachment position A to the detection position B, a detection result of the detection unit 60 is Off in a certain period, and then a detection result of the detection unit 60 is On again. That is, as illustrated in C of FIG. 10, even when a detection result of the detection unit 60 is Off once, in a case where the detection result is On at the detection position B, it is determined that an object is detected and there is an abnormal state. In a case where it is determined that there is an abnormal state based on a timing at which an object is no longer detected, it is difficult to determine that the case in C of FIG. 10 is abnormal.

As described above, according to the present disclosure, even in a mode in which abnormal states are different from each other, it is possible to determine an abnormal state under a common condition.

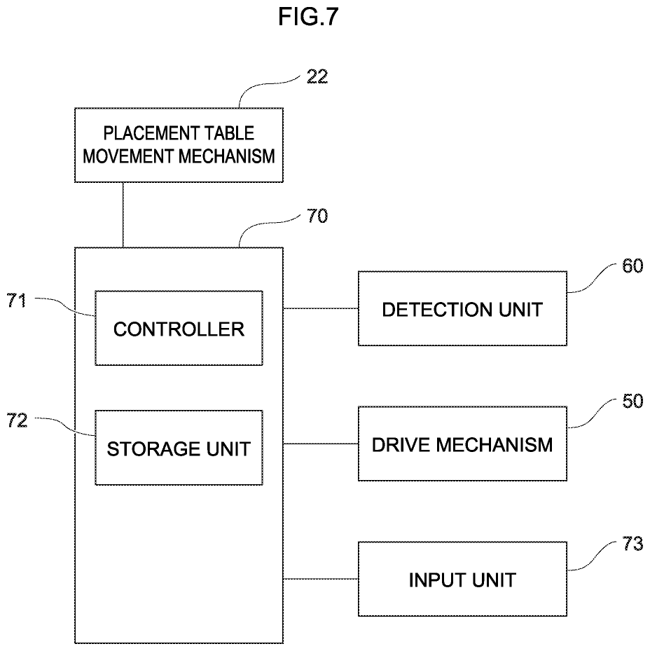

As illustrated in FIG. 1 and FIG. 7, the movement mechanism 22 of the placement table 23, the detection unit 60, and the drive mechanism 50 are electrically connected to the control unit 70. The control unit 70 is further connected to an input unit 73 that inputs an operation parameter of each unit of the load port 1.

The control unit 70 includes a controller 71 that receives various control programs and input data from the input unit 73 and controls an operation of each unit of the load port 1, and a storage unit 72 that stores various control programs and input data from the input unit 73.

The controller 71 includes a central processing unit (CPU), a memory, and the like, and controls an operation of each unit by executing a predetermined program. The storage unit 72 may include, for example, a storage medium such as a hard disk drive, a compact disk, a flash memory, a flexible disk, or a memory card. A control program is stored in the storage medium, and the control program is installed in the control unit 70 and is executed by the controller 71.

First, when detecting that the container 10 is placed on the placement table 23, the control unit 70 controls the movement mechanism 22 such that the placement table 23 is moved toward the plate 30 in the horizontal direction. When the container 10 comes into contact with the plate 30 and the port door 40, the locking mechanism 42 of the port door 40 is operated to unlock the lid 13. Next, the port door 40 is controlled such that the lid 13 is held by the port door 40 and the opening portion 31 of the plate 30 is opened. At this time, the control unit 70 controls the drive mechanism 50 such that the port door 40 that holds the lid 13 is moved from the attachment position A to the retracted position C and the port door 40 is lowered to a height at which the port door 40 does not face the opening portion 31 at the retracted position C. Next, the substrate W is taken out by the transfer arm in the substrate transfer device, a series of processing is performed by the process device, and the substrate W is returned to the container 10 via the substrate transfer device. Thereafter, when the port door 40 rises to a height at which the port door 40 faces the opening portion at the retracted position C, the detection unit 60 detects a protrusion state of the substrate W from the container 10. The control unit 70 determines a protrusion state of the substrate W from the container 10 based on the detection result. Then, the port door 40 that holds the lid 13 is aligned with the opening portion 31 of the plate 30, and the lid 13 is locked by the locking mechanism 42. Thus, the container 10 is sealed.

After the lid 13 is locked, the control unit 70 controls the drive mechanism 50 such that the port door 40 is moved from the attachment position A to the detection position B. Then, the control unit 70 controls the detection unit 60 in a state in which the port door 40 is stopped at the detection position B such that the detection unit 60 detects whether or not the port door 40 holds the lid 13. Further, the control unit 70 determines the presence or absence of an abnormal state related to attachment and detachment of the lid 13 based on the detection result of the detection unit 60.

The control unit 70 moves the port door 40 from the attachment position A to the detection position B based on a command value which is input to the input unit 73, and stops the port door 40 when the port door 40 reaches the detection position B. As the command value, one of or any combination of a movement distance and a movement time from the attachment position A to the detection position B can be used.

In the present embodiment, for example, the control unit 70 moves the port door 40 from the attachment position A to the detection position B based on the command value which is input to the input unit 73 and then stops the port door 40. For example, a pulse value may be used as the command value of the movement distance. A predetermined pulse value corresponding to the attachment position A may be set as a reference, and a pulse value when the port door 40 is moved and stopped at the detection position B may be set as the command value. Alternatively, a pulse value corresponding to a value of a distance between the attachment position A and the detection position B may be set as the command value. In addition, a time obtained by using a timer may be input as a command value for stopping the port door 40 at the detection position B. A time for which the port door 40 moves from the attachment position A to the detection position B may be calculated based on a distance between the attachment position A and the detection position B and a movement speed of the port door 40 that moves from the attachment position A to the detection position B, and the calculated time may be set as the command value. That is, a value of or any combination of the pulse value and the value of the movement time from the attachment position A to the detection position B can be used as the command value. Note that the command value does not necessarily need to be input to the input unit 73, and the command value may be incorporated in the control program stored in the storage unit 72.

The control unit 70 controls the drive mechanism 50 such that the port door 40 is stopped at the detection position B. By performing abnormal state detection in a state in which the port door 40 is stopped at the detection position B in this way, more accurate abnormal state detection can be performed. In a case where it is determined that attachment of the lid 13 is normal based on the detection result of the detection unit 60, the control unit 70 controls the drive mechanism 50 such that the port door 40 is moved to the attachment position A. In this way, the container 10 is transferred to the next process, and the port door 40 waits at the attachment position A until the next container 10 is loaded.

Further, in a case where it is determined that there is an abnormal state related to attachment of the lid 13, the control unit 70 controls the drive mechanism 50 such that the port door 40 is emergently stopped at the detection position B, an alarm is output, or the port door 40 is emergently stopped and an alarm is output.

In the present embodiment, abnormal state detection is performed in a state in which the port door 40 is stopped at the detection position B, and thus, a time required for the abnormal state determination method can be shortened as compared with a case where the port door 40 is further moved to the retracted position C and abnormal state determination is performed.

The load port 1 according to the present embodiment includes the placement portion 20 on which the container 10 in which a substrate W is accommodated is placed, the plate 30 having the opening portion 31 through which the substrate W is inserted and removed in a state of being adjacent to the container 10, the port door 40 that opens and closes the opening portion 31, includes the engaging portion 411 to be engaged with the engagement portion 13b of the lid 13 of the container 10, and comes into contact with the first surface 13F of the lid 13, a drive mechanism 50 that moves the port door 40 to the attachment position A close to the plate 30, the detection position B between the attachment position A and the retracted position C, and the retracted position C separated from the plate 30, the detection unit 60, and the control unit 70. The control unit 70 moves the port door 40 from the attachment position A to the detection position B, and in a state in which the port door 40 is stopped at the detection position B, the detection unit 60 detects whether or not the port door 40 holds the lid 13. The presence or absence of an abnormal state related to the attachment state of the lid 13 is determined based on the detection result of the detection unit 60. Further, in a case where it is determined that there is an abnormal state, the port door 40 is emergently stopped at the detection position B, an alarm is output, or the port door 40 is emergently stopped and an alarm is output. It is possible to detect more patterns of assumed abnormalities related to attachment and detachment of the lid without requiring an additional complicated mechanism, and thus, it is possible to more accurately determine the presence or absence of an abnormal state. That is, it is possible to more accurately determine the state related to attachment and detachment of the lid.

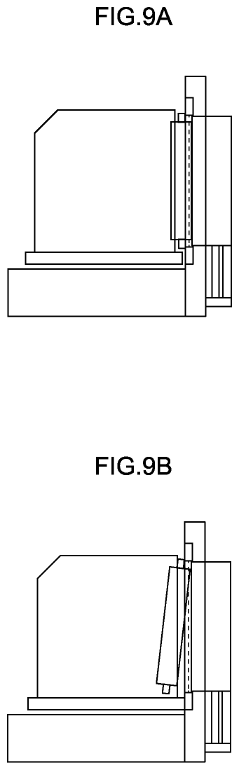

As the patterns of abnormalities, for example, as illustrated in FIG. 9A, there is a case where the latch 13a of the lid 13 is not fitted into the groove 10a of the main body portion 11 of the container 10 and the lid 13 is held in a state of being in contact with the holding surface 40a of the port door 40. Further, as illustrated in FIG. 9B, there are a case where the latch 13a of the lid 13 is not fitted into the groove 10a of the main body portion 11 of the container 10 and the lid 13 is not held by the port door 40, a case where the latch 13a of the lid is not fitted into the groove 10a of the main body portion 11 of the container 10 and the lid is held in a state of being separated from the port door (refer to FIG. 6), and the like.

In the case of FIG. 9A, since the lid 13 is present in the detection region O of the detection unit 60, the detection unit 60 detects that an object is present in the detection region O, and thus, it is determined that there is an abnormal state. Further, even in the case of FIG. 9B, since the lid 13 is not fitted with the latch 13a and is inclined and a part of the lid 13 is included in the detection region O, the detection unit 60 detects that an object is present in the detection region O, and thus, it is determined that there is an abnormal state.

In addition, the detection position B at which the port door 40 is stopped is a position at which the detection unit 60 is disposed in the region S between the tip portion 411a of the engaging portion 411 and the second surface 13B of the lid 13 in a state in which the first surface 13F of the lid 13 is in contact with the holding surface 40a of the port door 40. As described above, by controlling the movement of the port door 40, it is possible to detect more patterns of assumed abnormalities related to attachment and detachment of the lid without requiring an additional complicated mechanism, and thus, it is possible to more accurately determine the presence or absence of an abnormal state. That is, it is possible to more accurately determine the state related to attachment and detachment of the lid.

Further, in the present embodiment, the control unit 70 moves the port door 40 from the attachment position A to the detection position B based on the command value which is input to the input unit 73. One of or any combination of the movement distance and the movement time from the attachment position A can be used as the command value. With this configuration, the detection position B can be flexibly set even in a case where there is an individual difference in the thickness of the lid 13 and the length of the engaging portion 411.

In the present embodiment, the detection unit 60 includes optical sensors including the light projecting unit 61 and the light receiving unit 62, and the light projecting unit 61 and the light receiving unit 62 are disposed above and below the center of the plate 30 in the horizontal direction (X-axis direction) with the opening portion 31 interposed therebetween. With this configuration, the detection unit 60 can be used for detection of the protrusion of the substrate W in addition to determination of an attachment abnormal state.

When it is determined that the attachment and detachment of the lid 13 is normal, the control unit 70 moves the port door 40 to the attachment position A. That is, in order to determine an abnormal state, it is only required to move the port door 40 to the detection position B. In a case where a normal state is determined, it is possible to immediately move the port door 40 to the attachment position A and cause the port door 40 to operate in a standby state. Therefore, it is not necessary to move the port door 40 to the retracted position C for determination of an abnormal state, and thus, it is possible to quickly perform abnormal state determination.

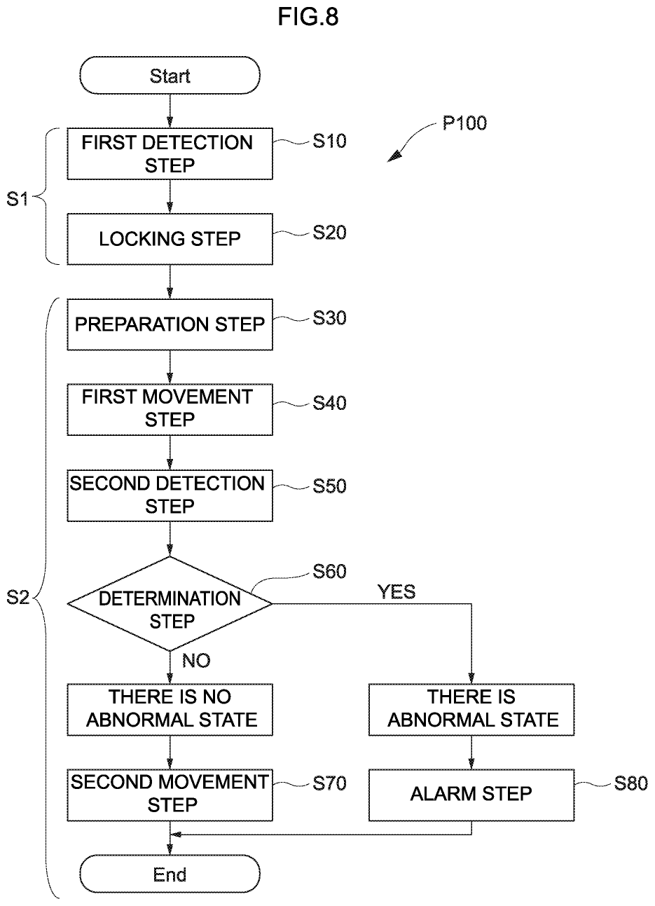

A method of determining a state related to attachment and detachment of the lid 13 (abnormal state determination) in the load port 1 having the above configuration will be described below with reference to FIG. 8.

FIG. 8 is a flowchart of an abnormal state determination method P100 according to the present embodiment.

In FIG. 8, S1 represents a lid attachment step of the container 10, and S2 represents an abnormal state determination step. First, after processing for all the substrates W in the container 10 is completed and all the substrates W are accommodated in the container 10, the port door 40 is moved from the retracted position C to the attachment position A. When the port door 40 moves up and down at the retracted position C, the optical sensors detect whether or not the substrate W protrudes. When the substrate W is included in the detection region O of the detection unit 60, it is determined that the substrate W protrudes. (First Detection Step S10) Thereafter, the locking mechanism 42 of the port door 40 is engaged with the locking hole of the lid 13, and the lid 13 is locked (locking step S20).

Next, the process proceeds to the abnormal state determination step S2. First, suction of the port door 40 that holds the lid 13 is released. Specifically, for example, forming of a vacuum state through the suction hole 411b provided in the engaging portion 411 of the port door 40 is stopped. As described above, in a case where a vacuum state is formed through the suction hole 411b, the inside of the suction pad 412 has a negative pressure, and thus, the lid 13 can be held. (Preparation Step S30) Thereafter, the port door 40 is moved from the attachment position A to the detection position B (first movement step S40). Next, in a state in which the port door 40 is stopped at the detection position B, the detection unit 60 detects whether or not the port door 40 holds the lid 13 (second detection step S50). Finally, based on a detection result of the detection unit 60, the control unit 70 determines a state related to attachment and detachment of the lid 13 (determines presence or absence of an abnormal state) (determination step S60).

Specifically, in the movement step S40, in a state in which the first surface 13F of the lid 13 is in contact with the holding surface 40a of the port door 40, the drive mechanism 50 is moved to the detection position B, which is a position at which the detection unit 60 is disposed in the region S between the tip portion 411a of the engaging portion 411 and the second surface 13B of the lid 13.

The abnormal state determination step S2 further includes a determination step S60. In a case where the lid 13 is not detected in the detection step S50, it is determined that there is no abnormal state (NO). In a case where the lid 13 is detected in the detection step S50, it is determined that there is an abnormal state (YES).

When it is determined in the determination step S60 that there is no abnormal state (in a case where it is determined that attachment and detachment of the lid 13 is normal), the port door 40 is moved to the attachment position A (second movement step S70). Thus, a series of processing for the abnormal state determination step S2 is ended (End).

In a case where it is determined in the determination step S60 that there is an abnormal state (in a case where it is determined that there is an abnormal state related to attachment and detachment of the lid 13), the port door 40 is emergently stopped at the detection position B, an alarm is output, or the port door 40 is emergently stopped at the detection position B and an alarm is output (alarm step S80). Thus, a series of processing for the abnormal state determination step S2 is ended (End).

In the load port 1 according to the present embodiment, the port door 40 is moved from the attachment position A to the detection position B. In a state in which the port door 40 is stopped at the detection position B, the detection unit 60 detects whether or not the port door 40 holds the lid 13, and the presence or absence of an abnormal state related to the attachment state of the lid 13 is determined based on a detection result of the detection unit 60. With this configuration, it is possible to more accurately detect an abnormal state, and further, in a case where it is determined that there is an abnormal state, the port door 40 is emergently stopped at the detection position B, an alarm is output, or the port door 40 is emergently stopped at the detection position B and an alarm is output. It is possible to detect more patterns of assumed abnormalities related to attachment and detachment of the lid without requiring an additional complicated mechanism, and thus, it is possible to more accurately determine the presence or absence of an abnormal state. Examples of the patterns of abnormalities include a case where the latch 13a of the lid is not fitted into the groove 10a of the main body portion 11 and the lid is not held by the port door, a case where the latch 13a of the lid is not fitted into the groove 10a of the main body portion and the lid is held in a state of being in contact with the holding surface 40a of the port door, and a case where the latch 13a of the lid is not fitted into the groove 10a of the main body portion and the lid is held in a state of being separated from the port door.

In the abnormal state determination method P100 according to the present embodiment, the second detection step S50 includes a movement step of moving the drive mechanism 50 to a position at which the detection unit 60 is disposed in the region S between the tip portion 411a of the engaging portion 411 and the second surface 13B of the lid 13 in a state in which the first surface 13F of the lid 13 is in contact with the holding surface 40a of the port door 40. In this way, it is possible to detect more patterns of assumed abnormalities related to the attachment state of the lid without requiring an additional complicated mechanism, and thus, it is possible to more accurately determine the presence or absence of an abnormal state.

In the abnormal state determination method P100 according to the present embodiment, in a case where it is determined in the determination step S60 that attachment and detachment of the lid 13 is normal, the port door 40 is moved to the attachment position A. That is, in order to determine an abnormal state, it is only required to move the port door 40 to the detection position B. In a case where a normal state is determined, it is possible to immediately move the port door 40 to the attachment position A and cause the port door 40 to operate in a standby state. Therefore, it is not necessary to move the port door 40 to the retracted position C for determination of an abnormal state, and thus, it is possible to quickly perform abnormal state determination.

Note that the abnormal state determination method P100 may be implemented by storing a control program in a storage medium, installing the control program in the control unit 70, and causing the control unit 70 to execute a series of processing for the abnormal state determination method P100.

Although the present invention has been described based on the above embodiment, the present invention is not limited to the content of the above embodiment, and can be appropriately changed without departing from the present invention. That is, it is a matter of course that other embodiments, examples, operation techniques, and the like made by those skilled in the art based on the embodiment are all included in the scope of the present invention.

What is claimed is:

1. A load port, comprising:
a placement portion at which is placed a container accommodating a substrate;
a plate that has an opening portion through which the substrate is inserted and removed, in a state in which the opening portion is adjacent to the container;
a port door that opens and closes the opening portion, that includes an engaging portion configured to engage with an engagement portion of a lid of the container, and that holds the lid;
a drive mechanism that moves the port door to an attachment position in a vicinity of the plate, a retracted position separated from the plate, and a detection position between the attachment position and the retracted position;
a detection unit that detects at least the lid; and
a control unit that controls an operation of each unit,
wherein:
the engaging portion protrudes from a holding surface of the port door, a protrusion amount of the engaging portion being smaller than a thickness direction dimension of the lid that is held,
the lid has a second surface at an opposite side from a first surface, the first surface facing the port door,
the control unit moves the port door from the attachment position to the detection position, and determines a normal state or an abnormal state related to an attachment state of the lid based on a detection result of the detection unit in a state in which the port door is stopped at the detection position, and
the detection position is a position at which a detection region of the detection unit overlaps with a region between a tip portion of the engaging portion and the second surface of the lid in a case in which the first surface of the lid is contacting the holding surface of the port door.

2. The load port according to claim 1, wherein:
the detection unit is provided in the plate, and
the control unit sets, as the detection position, a position of the port door when the region overlaps with the detection region, moves the port door, and determines an attachment state of the lid attached to the container.

3. The load port according to claim 1, wherein:
the control unit moves the port door from the attachment position to the detection position based on a command value input to an input unit, and stops the port door when the port door reaches the detection position, and
the command value is one or any combination of a movement distance or a movement time from the attachment position to the detection position.

4. The load port according to claim 1, wherein:
the detection unit includes optical sensors including a light projecting unit and a light receiving unit, and
the light projecting unit and the light receiving unit are disposed above and below a center portion of the plate in a horizontal direction with the opening portion interposed therebetween.

5. The load port according to claim 1, wherein:
in a case in which it is determined that attachment of the lid is normal, the control unit moves the port door that is stopped at the detection position from the detection position to the attachment position, and
in a case in which it is determined that attachment of the lid is abnormal, the control unit outputs an alarm in a state in which the port door is stopped at the detection position.

6. The load port according to claim 1, wherein:
the detection unit further detects the substrate protruding from the container, and
the control unit determines a protrusion state of the substrate from the container in a case in which the port door that holds the lid is located at the retracted position.

7. The load port according to claim 1, wherein:
the normal state is a state in which the detection unit detects that there is no object present in the detection region in a case in which the port door is located at the detection position, and
the abnormal state is a state in which the detection unit detects that there is an object present in the detection region in a case in which the port door is located at the detection position.

8. An abnormal state determination method performed by a load port, the load port including a placement portion at which is placed a container accommodating a substrate, a plate that has an opening portion through which the substrate is inserted and removed, in a state in which the opening portion is adjacent to the container, a port door that opens and closes the opening portion and that includes an engaging portion configured to engage with an engagement portion of a lid of the container, a drive mechanism that moves the port door to an attachment position in a vicinity of the plate, a retracted position separated from the plate, and a detection position between the attachment position and the retracted position, a detection unit that detects at least the lid, and a control unit that controls an operation of each unit, the engaging portion protruding from a holding surface of the port door, a protrusion amount of the engaging portion being smaller than a thickness direction dimension of the lid that is held, and the lid having a second surface at an opposite side from a first surface, the first surface facing the port door, the method comprising:
detecting, by the detection unit, a state of the lid attached to the container in a state in which the port door is moved from the attachment position to the detection position and the port door is stopped at the detection position; and
determining a normal state or an abnormal state related to an attachment state of the lid based on a detection result of the detection unit,
wherein the detecting includes a movement step of moving the drive mechanism to a position at which a detection region of the detection unit overlaps with a region between a tip portion of the engaging portion and the second surface of the lid in a case in which the first surface of the lid is contacting the holding surface of the port door.

9. The abnormal state determination method according to claim 8, wherein, in a case in which it is determined that an attachment state of the lid is normal, the port door that is stopped at the detection position is moved from the detection position to the attachment position.

10. A storage medium, storing a program causing the control unit to execute the abnormal state determination method according to claim 8.
